(19) United States
(12) Patent Application Publication
(10) Pub. No.: US 2026/0090473 A1
(43) Pub. Date: Mar. 26, 2026

(54) SEMICONDUCTOR PACKAGE

(71) Applicant: Samsung Electronics Co., Ltd., Suwon-si (KR)

(72) Inventor: Youngbae KIM, Suwon-si (KR)

(73) Assignee: Samsung Electronics Co., Ltd., Suwon-si (KR)

(21) Appl. No.: 19/271,504

(22) Filed: Jul. 16, 2025

(30) Foreign Application Priority Data
Sep. 26, 2024 (KR) 10-2024-0130718

(51) Int. Cl. H01L 25/065; H01L 23/00; H01L 23/48

(52) U.S. Cl. CPC H10W 90/00; H10W 20/20; H10W 74/15; H10W 90/28; H10W 90/297; H10W 90/722; H10W 90/732

(57) ABSTRACT

A semiconductor package includes a base chip, a plurality of semiconductor chips stacked on the base chip, a cover chip on the plurality of semiconductor chips, adhesive layers below the cover chip and each of the plurality of semiconductor chips, and an encapsulant on the base chip and at least partially surrounding the plurality of semiconductor chips and the cover chip. The plurality of semiconductor chips includes at least one first semiconductor chip adjacent to the base chip, and at least one second semiconductor chip adjacent to the cover chip. The at least one second semiconductor chip has a second thickness smaller than a first thickness of the at least one first semiconductor chip. A width of each of the plurality of semiconductor chips is smaller than a width of the base chip, in a horizontal direction.

### CROSS-REFERENCE TO RELATED APPLICATION(S)

This application claims the benefit under 35 USC 119(a) of Korean Patent Application No. 10-2024-0130718 filed on Sep. 26, 2024 in the Korean Intellectual Property Office, the entire disclosure of which is incorporated herein by reference for all purposes.

### BACKGROUND

The present inventive concepts relate to a semiconductor package.

As electronic devices become lighter and more high-performance, the development of miniaturized, high-performance semiconductor packages may be also advantageous in the semiconductor package field. In order to implement miniaturization, lightness, high performance, and high reliability of semiconductor packages, research into and development of semiconductor packages with multilayer stacked semiconductor chips are continuously being undertaken.

### SUMMARY

Example embodiments relate to, for example, a semiconductor package having improved reliability.

According to some example embodiments, a semiconductor package may include a base chip; a plurality of semiconductor chips stacked on the base chip in a direction perpendicular to an upper surface of the base chip and including through-silicon vias; a cover chip on the plurality of semiconductor chips; bump structures below the cover chip and each of the plurality of semiconductor chips and electrically connected to the through-silicon vias; adhesive layers below the cover chip and each of the plurality of semiconductor chips, the adhesive layers at least partially surrounding each of the bump structures; and an encapsulant on the base chip and at least partially surrounding the plurality of semiconductor chips and the cover chip, wherein the plurality of semiconductor chips includes at least one first semiconductor chip adjacent to the base chip, and at least one second semiconductor chip adjacent to the cover chip, the at least one second semiconductor chip has a second thickness that is smaller than a first thickness of the at least one first semiconductor chip, and a width of each of the plurality of semiconductor chips in a horizontal direction is smaller than a width of the base chip in the horizontal direction.

According to some example embodiments, a semiconductor package may include a base chip; a plurality of semiconductor chips stacked on the base chip in a direction perpendicular to an upper surface of the base chip and including through-silicon vias; bump structures below each of the plurality of respective semiconductor chips and electrically connected to the through-silicon vias; adhesive layers below each of the plurality of semiconductor chips and at least partially surrounding each of the bump structures and; and an encapsulant on the base chip and at least partially surrounding side surfaces of each of the semiconductor chips, wherein the plurality of semiconductor chips includes lower semiconductor chips on the base chip and defining a lower chip stack, and upper semiconductor chips on the lower chip stack and defining an upper chip stack, a number of the lower semiconductor chips in the lower chip stack is greater than or equal to a number of the upper semiconductor chips in the upper chip stack, and a sum of individual thicknesses of the lower semiconductor chips is greater than a sum of individual thicknesses of the upper semiconductor chips.

According to some example embodiments, a semiconductor package may include a base chip; a plurality of semiconductor chips stacked on the base chip in a direction perpendicular to an upper surface of the base chip and including a through-silicon via electrically connected to the base chip; and an encapsulant on the base chip and covering at least a portion of each of the plurality of semiconductor chips and of the base chip, wherein the plurality of semiconductor chips includes a first semiconductor chip and a second semiconductor chip on the first semiconductor chip, a gap between the base chip and the first semiconductor chip is smaller than a gap between the base chip and the second semiconductor chip, and the first semiconductor chip has a first thickness that is greater than a second thickness of the second semiconductor chip.

### BRIEF DESCRIPTION OF DRAWINGS

The and other aspects, features, and advantages of the present inventive concepts will be more clearly understood from the following detailed description, taken in conjunction with the accompanying drawings, in which:

FIG. 1 is a cross-sectional view illustrating a semiconductor package according to some example embodiments;

FIG. 2 is a cross-sectional view illustrating a semiconductor package according to some example embodiments;

FIG. 3 is a cross-sectional view illustrating a semiconductor package according to some example embodiments;

FIG. 4 is a cross-sectional view illustrating a semiconductor package according to some example embodiments;

FIG. 5 is a simulation graph comparing accumulated warpage values in a semiconductor package in comparative examples and example of the present inventive concept according to the stacked chip order;

FIG. 6 is a cross-sectional view illustrating a semiconductor package according to some example embodiments; and

FIGS. 7A to 7E are cross-sectional views schematically illustrating a process of manufacturing a semiconductor package according to some example embodiments.

### DETAILED DESCRIPTION

Hereinafter, example embodiments will be described with reference to the attached drawings. Unless otherwise specifically stated, in this specification, terms such as ‘upper,’ ‘upper surface,’ ‘lower,’ ‘lower surface,’ ‘side surface,’ and the like are based on the drawings, and may actually vary depending on the direction in which components are disposed.

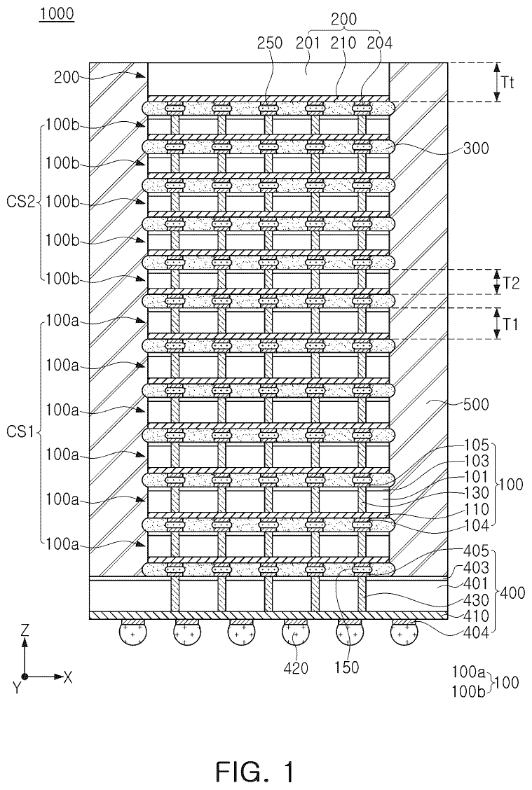

FIG. 1 is a cross-sectional view illustrating a semiconductor package 1000 according to some example embodiments.

Referring to FIG. 1, the semiconductor package 1000 of some example embodiments may include a base chip 400, a plurality of semiconductor chips 100, and a cover chip 200. In addition, the semiconductor package 1000 may further include an encapsulant 500 that seals the plurality of semiconductor chips 100 and the cover chip 200, on the base chip 400. As the number of stacked semiconductor chips increases, accumulated warpage in the stack in which the chips are stacked may become a problem, and further, a reliability problem of the semiconductor package may occur due to a warpage phenomenon of the base chip disposed below the chip stack. The present inventive concepts may address the warpage problem and provide a relatively highly reliable semiconductor package structure by disposing semiconductor chips having a relatively thick thickness in a lower region in a structure in which a plurality of semiconductor chips are stacked vertically.

The base chip 400 may, for example, include a semiconductor material such as a silicon (Si) wafer, but may also, for example be or include a PCB or glass substrate that does not include a semiconductor material, depending on some example embodiments. In some example embodiments, the base chip 400 may include a substrate 401, an upper protective layer 403, an upper pad 405, a lower pad 404, an element layer 410, and a through-silicon via (TSV) 430. However, if the base chip 400 is or includes a PCB or glass substrate that does not include a semiconductor material, the base chip 400 may not include an element layer and a TSV.

The base chip 400 may be or include, for example, a buffer chip that includes a plurality of logic elements and/or memory elements in the element layer 410. Accordingly, the base chip 400 may transmit signals from a plurality of semiconductor chips 100 stacked thereon to the outside, and may also transmit signals and/or power from the outside to the plurality of semiconductor chips 100. The base chip 400 may, for example, perform both logic and memory functions through logic elements and memory elements, but according to some example embodiments, the base chip 400 may perform only logic functions by including only logic elements.

The substrate 401 may include, for example, a semiconductor element such as, for example, silicon or germanium (Ge), or a compound semiconductor such as silicon carbide (SiC), gallium arsenide (GaAs), indium arsenide (InAs), or indium phosphide (InP), but example embodiments are not limited thereto. The substrate 401 may have a silicon-on-insulator (SOI) structure. The substrate 401 may include a conductive region, for example, a well doped with impurities, or a structure doped with impurities. The substrate 401 may include various element isolation structures such as, for example, a shallow trench isolation (STI) structure.

The upper protective layer 403 is formed on the upper surface of the substrate 401 and may protect the substrate 401. The upper protective layer 403 may be formed as an insulating layer such as, for example, a silicon oxide film, a silicon nitride film, a silicon oxynitride film, or the like, but the material of the upper protective layer 403 is not limited to the above materials. For example, the upper protective layer 403 may be formed of a polymer such as Polyimide (PI). Although not illustrated in the drawing, a lower protective layer may be further formed on the lower surface of the element layer 410.

The upper pad 405 may be disposed on the upper protective layer 403. The upper pad 405 may include, for example, at least one of aluminum (Al), copper (Cu), nickel (Ni), tungsten (W), platinum (Pt), or gold (Au). The lower pad 404 may be disposed below the element layer 410 and may include a material similar to a material of the upper pad 405. However, the materials of the upper pad 405 and the lower pad 404 are not limited to the materials above.

The element layer 410 may be disposed on the lower surface of the substrate 401 and may include one or more various types of elements. For example, the element layer 410 may include various active devices and/or passive devices such as FETs such as, for example, planar Field Effect Transistors (FETs) or FinFETs, memory elements such as flash memory, Dynamic Random Access Memory (DRAMs), Static Random Access Memory (SRAMs), Electrically Erasable Programmable Read-Only Memory (EEPROMs), Phase-change Random Access Memory (PRAMs), Magnetoresistive Random Access Memory (MRAMs), Ferroelectric Random Access Memory (FeRAMs), and Resistive Random Access Memory (RRAMs), logic devices such as ANDs, ORs and NOTs, system Large Scale Integration (LSIs), CMOS Imaging Sensors (CISs), and Micro-Electro-Mechanical Systems (MEMSs), but example embodiments are not limited thereto.

The element layer 410 may include interlayer insulating layers and interconnection layers on the elements. The interlayer insulating layers may include silicon oxide or silicon nitride. The interconnection layer may include multilayer interconnections and/or vertical contacts. The interconnection layer may connect the elements of the element layer 410 to each other, connect the elements to the conductive region of the substrate 401, and/or connect the elements to the external connection terminal 420.

A through-silicon via (TSV) 430 may penetrate the substrate 401 in a vertical direction (Z-direction) and provide an electrical path connecting the upper pads 405 and the lower pads 404. The through-silicon via 430 may include a conductive plug and a barrier film surrounding the conductive plug. The conductive plug may include a metal material, such as tungsten (W), titanium (Ti), aluminum (Al), or copper (Cu). The conductive plug may be formed by a plating process, a PVD process, or a CVD process. The barrier film may include an insulating barrier film or/and a conductive barrier film. The insulating barrier film may be formed of an oxide film, a nitride film, a carbide film, a polymer, or combinations thereof. The conductive barrier film may be disposed between the insulating barrier film and the conductive plug. The conductive barrier film may include a metal compound, such as, for example, tungsten nitride (WN), titanium nitride (TiN), or tantalum nitride (TaN). The barrier film may be formed by, for example, a PVD process or a CVD process, but example embodiments are not limited thereto.

The plurality of semiconductor chips 100 may include a plurality of first semiconductor chips 100a stacked on a base chip 400 and a plurality of second semiconductor chips 100b stacked on the plurality of first semiconductor chips 100a. The plurality of first semiconductor chips 100a may be referred to as lower semiconductor chips 100a disposed in a lower region among the plurality of semiconductor chips 100 and may define a lower chip stack CS1, and the plurality of second semiconductor chips 100b may be referred to as upper semiconductor chips 100b disposed in an upper region among the plurality of semiconductor chips 100 and may define an upper chip stack CS2. The gap between the base chip 400 and the first semiconductor chip 100a may be smaller than the gap between the base chip 400 and the second semiconductor chip 100b.

As illustrated in FIG. 1, in some example embodiments, the plurality of first semiconductor chips 100a may include six first semiconductor chips 100a, and the plurality of second semiconductor chips 100b may include five second semiconductor chips 100b, but is not limited thereto. In the horizontal direction, the widths of the plurality of respective (for example, the width of each of) first semiconductor chips 100a and the plurality of respective second semiconductor chips 100b may be the same, and the widths may be smaller than the width of the base chip 400, but is not limited thereto. Respective side surfaces (for example, side surfaces of each) of the plurality of first semiconductor chips 100a and the plurality of second semiconductor chips 100b may be aligned.

The number of lower semiconductor chips 100a disposed in the lower chip stack CS1 may be greater than or equal to the number of upper semiconductor chips 100b disposed in the upper chip stack CS2. The plurality of first semiconductor chips 100a are disposed adjacent to the base chip 400 and have a first thickness T1, and the plurality of second semiconductor chips are disposed adjacent to the cover chip 200 and may have a second thickness T2 smaller than the first thickness T1. For example, the first thickness T1 may be in a range of about 43 μm to about 60 μm, and the second thickness T2 may be in a range of about 40 μm to about 48 μm, but is not limited thereto. The first thickness T1 and the second thickness T2 may be determined in consideration of the degree of warpage or potential warpage of the plurality of semiconductor chips 100, the thickness (Tt) of the cover chip 200, the overall thickness of the semiconductor package 1000, and the like. The sum total (for example, the sum) of thicknesses of the plurality of respective first semiconductor chips 100a may have a value greater than the sum total of thicknesses of the plurality of respective second semiconductor chips 100b.

In the semiconductor package 1000 according to some example embodiments, by disposing relatively thick semiconductor chips 100a in the lower chip stack CS1 disposed on the upper surface of the base chip 400, the total thickness of the respective semiconductor chips 100a disposed in the lower chip stack CS1 may be greater than the total thickness of the respective semiconductor chips 100b disposed in the upper chip stack CS2, thereby reducing the accumulated warpage problem caused by stacking multiple semiconductor chips.

Each of the plurality of semiconductor chips 100 may include a substrate 101, an upper protective layer 103, an upper pad 105, a lower pad 104, an element layer 110, and a through-silicon via 130. In the drawing, the number of the plurality of semiconductor chips 100 is illustrated as 11, but the number of semiconductor chips 100 in the example embodiments is not limited thereto. For example, 16 or more semiconductor chips may be stacked on the base chip 400. The components of the plurality of semiconductor chips 100 may have similar characteristics to those described for the components of the base chip 400, and the characteristics may be understood as characteristics that are equally applied to the first semiconductor chip 100a and the second semiconductor chip 100b.

The element layer 110 may include a plurality of memory elements. For example, the element layer 210 may include one or more of volatile memory elements such as DRAM and SRAM, or nonvolatile memory elements such as PRAM, MRAM, FeRAM, or RRAM. For example, in the semiconductor package 1000 according to some example embodiments, the semiconductor chip 100 may include DRAM devices in the element layer 210. Accordingly, the semiconductor package 1000 according to some example embodiments may be used for High Bandwidth Memory (HBM) products, Electro Data Processing (EDP) products, and the like.

The element layer 110 may include a multilayer interconnection layer thereunder. The multilayer interconnection layer may have the same or similar characteristics to those described for the interconnection layer of the element layer 410 in the base chip 400. Accordingly, the devices of the element layer 110 may be electrically connected to the bump 220 through the multilayer interconnection layer. In some example embodiments, the base chip 400 includes a plurality of logic elements and/or memory elements in the element layer 410 and may be referred to as a buffer chip, a control chip, or the like, depending on the function thereof, while the semiconductor chip 100 includes a plurality of memory elements in the element layer 110 and may be referred to as a core chip.

The cover chip 200 may be disposed on an uppermost semiconductor chip 100 among the plurality of semiconductor chips 100. The cover chip 200 may be configured to have the same or similar function as the plurality of semiconductor chips 100, as described above, and may be referred to as an upper core chip. The cover chip 200 may or may not include a through-silicon via (TSV) penetrating at least a portion of the substrate 201, and may be electrically connected to the plurality of semiconductor chips 100 through lower pads 204 and bump structures 250 disposed below the element layer 210. Referring to FIG. 1, the cover chip 200 may have the same width in the horizontal direction as the plurality of semiconductor chips 100. The cover chip 200 may have a thickness (Tt) greater than the first thickness T1 of the first semiconductor chip 100a and the second thickness T2 of the second semiconductor chip 100b among the plurality of semiconductor chips, but is not limited thereto.

The bump structures 150 are disposed below the cover chip 200 and the plurality of respective semiconductor chips 100, and may be electrically connected to the through-silicon vias 130 of the plurality of respective semiconductor chips 100. The bump structures 150 are disposed on the connection pads 104 on the lower surface of the element layer 110, and may be connected to the elements of the element layer 110 through wiring of the multilayer interconnection layer. The bump structures 150 may electrically connect the semiconductor chip 100 and the base chip 400. The bump structures 150 may include, for example, solder, but may include both pillars and solder according to some example embodiments. The pillars have a cylindrical shape, or a polygonal pillar shape such as a quadrangular pillar or an octagonal pillar, and may include, for example, nickel (Ni), copper (Cu), palladium (Pd), platinum (Pt), gold (Au), or combinations thereof. The solder has a spherical or ball shape, and may include, for example, tin (Sn), indium (In), bismuth (Bi), antimony (Sb), copper (Cu), silver (Ag), zinc (Zn), lead (Pb), and/or alloys thereof. The alloy may include, for example, Sn—Pb, Sn—Ag, Sn—Au, Sn—Cu, Sn—Bi, Sn—Zn, Sn—Ag—Cu, Sn—Ag—Bi, Sn—Ag—Zn, Sn—Cu—Bi, Sn—Cu—Zn, Sn—Bi—Zn, or the like, but example embodiments are not limited thereto.

The adhesive layers 300 may surround the side surfaces of the bump structures 150, below the cover chip 200 and the plurality of respective semiconductor chips 100 and secure the cover chip 200 and the plurality of semiconductor chips 100. The adhesive layers 300 may protrude outwardly from the side surfaces of the plurality of semiconductor chips 100, as illustrated in FIG. 1, and cover at least a portion of the side surfaces of the semiconductor chips 200. The adhesive layers 300 may be or include a Non-Conductive Film (NCF), but is not limited thereto, and may include, for example, any of the various kinds of polymer films that may be subjected to a thermocompression process. By the thermocompression process, at least a portion of the adhesive layers 300 may flow toward the outside of the semiconductor chip 100 and form an extended region that protrudes beyond respective side surfaces of the plurality of semiconductor chips 100. In the horizontal direction, a maximum width of each of the adhesive layers 300 may be greater than a width of each of the plurality of semiconductor chips 100, but is not limited thereto.

The encapsulant 500 is disposed on the base chip 400 and may seal at least portions of the base chip 400, the plurality of semiconductor chips 100 and the adhesive layers 300. As illustrated in FIG. 1, the upper surface of the encapsulant 500 may be located at the same level as the upper surface of an uppermost semiconductor chip among the plurality of semiconductor chips 100. In such a case, the upper surface of the uppermost semiconductor chip may be exposed from (for example, at least partially uncovered by) the encapsulant 500. The encapsulant 500 may include, for example, Epoxy Mold Compound (EMC), but the material of the encapsulant 500 is not particularly limited.

The external connection terminal 420 is disposed on the lower pad 404 below the base chip 400, is connected to the interconnection layer or TSV 430 inside the element layer 410, and may be electrically connected to the base chip 400. The external connection terminal 420 may be formed as a solder ball. However, depending on some example embodiments, the external connection terminal 420 may have a structure including a pillar and solder. The semiconductor package 1000 may be mounted on an external substrate such as an interposer or a package substrate through the external connection terminal 420.

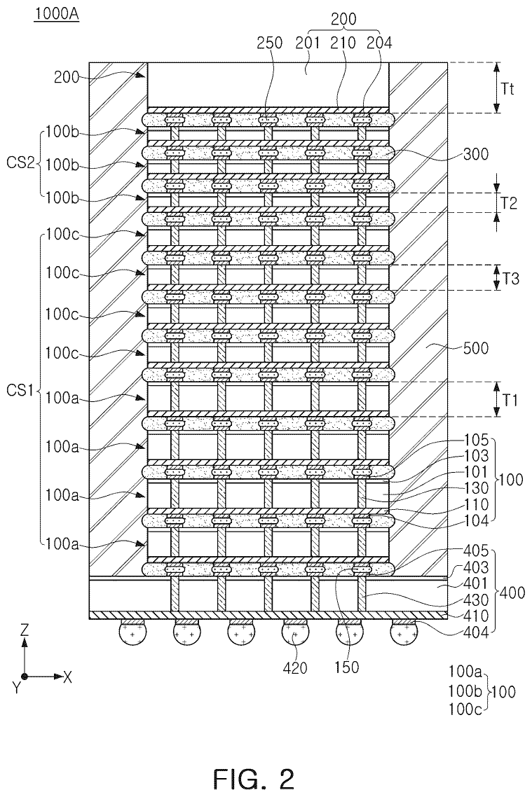

FIG. 2 is a cross-sectional view illustrating a semiconductor package 1000A according to some example embodiments.

Referring to FIG. 2, a semiconductor package 1000A of some example embodiments may have the same or similar features as described with reference to FIG. 1, except that the plurality of semiconductor chips 100 include first to third semiconductor chips 100a, 100b and 100c having different thicknesses. The semiconductor package 1000A according to some example embodiments may include a plurality of first semiconductor chips 100a stacked on a base chip 400 and second semiconductor chips 100b stacked on the first semiconductor chips 100a, and may further include third semiconductor chips 100c disposed between the first semiconductor chips 100a and the second semiconductor chips 100b. The plurality of first semiconductor chips 100a may have a first thickness T1, the plurality of second semiconductor chips may have a second thickness T2 smaller than the first thickness T1, and each of the plurality of third semiconductor chips 100c may have a third thickness T3 smaller than the first thickness T1 and larger than the second thickness T2. In the semiconductor package 1000A according to some example embodiments, the lower chip stack CS1 may include four first semiconductor chips 100a and four third semiconductor chips 100c, and the upper chip stack CS2 may include three second semiconductor chips 100b, but the number of semiconductor chips included in each chip stack is not limited thereto. In the semiconductor package 1000A according to some example embodiments, three or more groups of semiconductor chips having different thicknesses may be disposed, and by enabling the sum total of the thicknesses of the semiconductor chips disposed in the upper region, to be smaller than the sum total of the thicknesses of the semiconductor chips disposed in the lower region, the degree of accumulated warpage within the semiconductor package 1000A may be reduced.

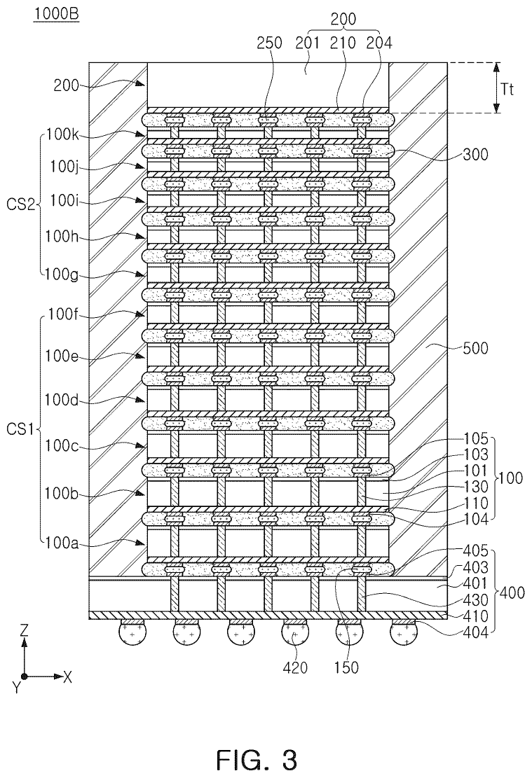

FIG. 3 is a cross-sectional view illustrating a semiconductor package 1000B according to some example embodiments.

Referring to FIG. 3, the semiconductor package 1000B of some example embodiments may have the same or similar features as those described with reference to FIGS. 1 and 2, except that respective thicknesses of the plurality of semiconductor chips 100 are all different. The semiconductor package 1000B according to some example embodiments may include a plurality of semiconductor chips 100 stacked on a base chip 400, and the plurality of semiconductor chips 100 may include first to eleventh semiconductor chips 100a, 100b, 100c, 100d, 100e, 100f, 100g, 100h, 100i, 100j and 100k respectively having a different thickness. The lower chip stack CS1 may include first to sixth semiconductor chips 100a, 100b, 100c, 100d, 100e and 100f, and the upper chip stack CS2 may include seventh to eleventh semiconductor chips 100g, 100h, 100i, 100j and 100k, but the number of semiconductor chips included in each chip stack is not limited thereto. Respective (for example, individual) thicknesses of the plurality of semiconductor chips 100 may become thinner from the bottom to the top of the semiconductor package 1000B, or from the base chip 400 to the cover chip 200. For example, the thickness of the second semiconductor chip 100b may be thinner than the thickness of the first semiconductor chip 100a, the thickness of the sixth semiconductor chip 100f may be thinner than the thickness of the fifth semiconductor chip 100e, and the thickness of the eleventh semiconductor chip 100k may be thinner than the thickness of the first semiconductor chip 100a. The sum total of the thicknesses of the respective (for example, individual) semiconductor chips disposed in the lower chip stack CS1 may be greater than the sum total of the thicknesses of the respective (for example, individual) semiconductor chips disposed in the upper chip stack CS2. In the semiconductor package 1000B according to some example embodiments, by enabling the sum total of the thicknesses of the semiconductor chips disposed in the upper region to be smaller than the sum total of the thicknesses of the semiconductor chips disposed in the lower region, the degree of accumulated warpage in the semiconductor package 1000B may be reduced or limited, and by making the thicknesses of the disposed semiconductor chips different from each other, the degree of structural freedom may be secured or improved.

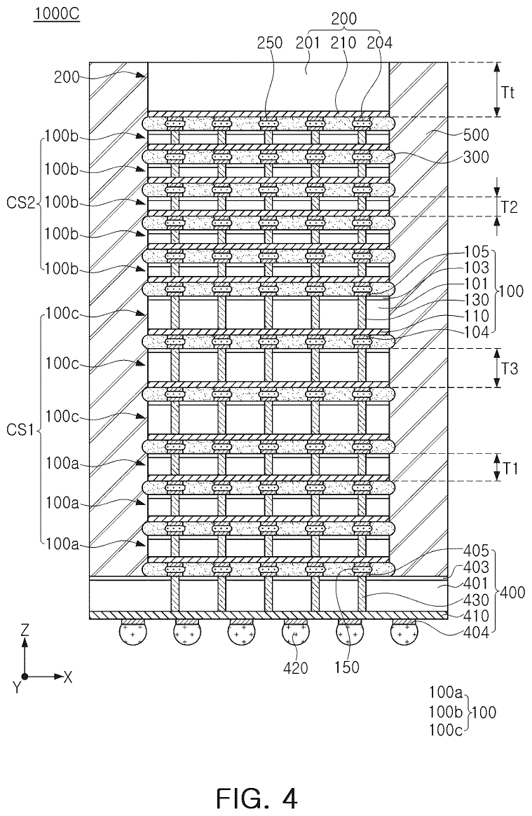

FIG. 4 is a cross-sectional view illustrating a semiconductor package 1000C according to some example embodiments.

Referring to FIG. 4, the semiconductor package 1000C of some example embodiments may have the same or similar features as those described with reference to FIGS. 1 to 3, except that a third semiconductor chip 100c that is thicker than the first semiconductor chip 100a is disposed on the first semiconductor chip 100a in the lower chip stack CS1. The semiconductor package 1000C according to some example embodiments may include a plurality of first semiconductor chips 100a stacked on a base chip 400 and second semiconductor chips 100b stacked on the first semiconductor chips 100a, and may further include third semiconductor chips 100c disposed between the first semiconductor chips 100a and the second semiconductor chips 100b. The plurality of first semiconductor chips 100a may have a first thickness T1, the plurality of second semiconductor chips may have a second thickness T2 smaller than the first thickness T1, and each of the plurality of third semiconductor chips 100c may have a third thickness T3 greater than the first thickness T1 and the second thickness T2. In the semiconductor package 1000C according to some example embodiments, the lower chip stack CS1 may include three first semiconductor chips 100a and three third semiconductor chips 100c, and the upper chip stack CS2 may include five second semiconductor chips 100b, but the number of semiconductor chips included in each chip stack is not limited thereto. In the semiconductor package 1000C according to some example embodiments, in a structure in which the sum total of thicknesses of semiconductor chips disposed in the upper region is smaller than the sum total of thicknesses of semiconductor chips disposed in the lower region, and on the lowermost first semiconductor chip 100a among a plurality of semiconductor chips 100, the third semiconductor chip 100c that is thicker than the first semiconductor chip 100a is disposed, and accordingly, the degree of accumulated warpage within the semiconductor package 1000C may be reduced, and at the same time, the degree of structural freedom may be increased or ensured.

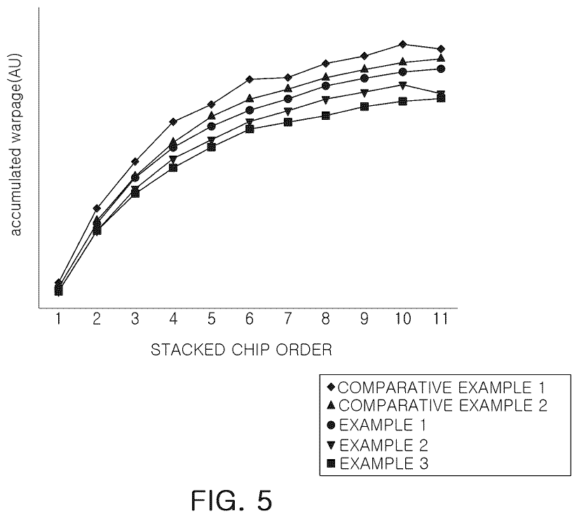

FIG. 5 is a graph illustrating simulation results of the accumulated warpage degree (Y-axis variable) according to the stacked chip order (X-axis variable) in the semiconductor package according to examples of the present inventive concept and comparative examples.

Examples 1 to 3 and Comparative Examples 1 to 2 in FIG. 5 may correspond to examples in which the thicknesses of the lower semiconductor chips 100a forming the lower chip stack CS1 and the upper semiconductor chips 100b forming the upper chip stack CS2 are different in a plurality of semiconductor chips 100 stacked on the base chip 400.

Example 1 may correspond to some example embodiments in which the first thickness T1 of each of the lower semiconductor chips 100a is about 5 μm thicker than the second thickness T2 of each of the upper semiconductor chips 100b.

Example 2 may correspond to some example embodiments in which the first thickness T1 of each of the lower semiconductor chips 100a is about 10 μm thicker than the second thickness T2 of each of the upper semiconductor chips 100b, and may be understood as a simulation result value for the example embodiments illustrated in FIG. 1.

Example 3 may correspond to some example embodiments in which the respective (for example, individual) thicknesses of the plurality of semiconductor chips 100 are all different, and the thickness difference between the first semiconductor chip 100a and the second semiconductor chip 100b adjacent to each other is about 2 μm, and may be understood as a simulation result value for the example embodiments illustrated in FIG. 3.

Comparative Example 1 may correspond to an example in which the first thickness T1 of each of the lower semiconductor chips 100a is the same as the second thickness T2 of each of the upper semiconductor chips 100b.

Comparative Example 2 may correspond to an example in which the first thickness T1 of each of the lower semiconductor chips 100a is about 5 μm thinner than the second thickness T2 of each of the upper semiconductor chips 100b.

In the example embodiments and comparative examples in FIG. 5, the ratio of the total thickness of the respective upper semiconductor chips 100b disposed in the upper chip stack CS2 to the total thickness of the respective lower semiconductor chips 100a disposed in the lower chip stack CS1 may decrease in the order of Comparative Example 1, Comparative Example 2, Example 1, Example 2, and Example 3. Referring to FIG. 5, it can be observed that the expected accumulated warpage value decreases in the order of Comparative Example 1, Comparative Example 2, Example 1, Example 2, and Example 3 depending on the stacked chip order. In summary, a relatively thick semiconductor chip is disposed in a lower region within a semiconductor package, and as the ratio of the sum total of the thicknesses of the respective upper semiconductor chips 100b disposed within the upper chip stack CS2 to the sum total of the thicknesses of the respective lower semiconductor chips 100a disposed within the lower chip stack CS1 decreases, the expected accumulated warpage value according to the stacked chip order also decreases, thereby providing a semiconductor package having improved reliability.

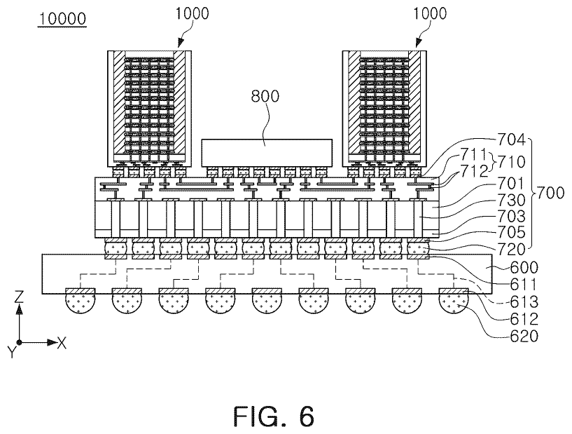

Referring to FIG. 6, a semiconductor package 10000 of some example embodiments may include a package substrate 600, an interposer substrate 700, and at least one chip structure 1000. In addition, the semiconductor package 10000 may further include a logic chip and/or a processor chip 800, for example disposed adjacent to the chip structure 1000, on the interposer substrate 700.

The package substrate 600 may include a lower pad 612 disposed on a lower surface of the body, an upper pad 611 disposed on an upper surface of the body, and a redistribution circuit 613 electrically connecting the lower pad 612 and the upper pad 611. The package substrate 600 is a support substrate on which an interposer substrate 700, a logic chip 800, and a chip structure 1000 are mounted, and may be or include a semiconductor package substrate including, for example, a printed circuit board (PCB), a ceramic substrate, a glass substrate, a tape interconnection substrate, and/or the like. The body of the package substrate 600 may include different materials depending on the type of the substrate. For example, when the package substrate 600 is a printed circuit board, the substrate may be in the form in which a body copper-clad laminate or a copper-clad laminate is provided with an interconnection layer additionally stacked on one side or both sides. A solder resist layer may be formed on the lower surface and the upper surface of the package substrate 600, respectively. The lower pads and upper pads 612 and 611 and the redistribution circuit 613 may form an electrical path connecting the lower surface and the upper surface of the package substrate 600. The lower pads and upper pads 612 and 611 and the redistribution circuit 613 may include, for example, a metal material, for example, at least one metal from among copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), and carbon (C), or an alloy including two or more metals. The redistribution circuit 613 may include multilayer redistribution layers and vias connecting the same. An external connection terminal 620 connected to the lower pad 612 may be disposed on the lower surface of the package substrate 600. The external connection terminal 620 may include, for example, tin (Sn), indium (In), bismuth (Bi), antimony (Sb), copper (Cu), silver (Ag), zinc (Zn), lead (Pb), and/or any alloys thereof.

The interposer substrate 700 may include a substrate 701, a lower protective layer 703, a lower pad 705, an interconnection layer 710, a bump 720, and a through-electrode 730. The chip structure 1000 and the processor chip 800 may be stacked on the package substrate 600 via the interposer substrate 700. The interposer substrate 700 may electrically connect the chip structure 1000 and the processor chip 800 to each other.

The substrate 701 may be formed of or include, for example, any one of a silicon, an organic, a plastic, and a glass substrate. When the substrate 701 is a silicon substrate, the interposer substrate 700 may be referred to as a silicon interposer. Also, when the substrate 701 is an organic substrate, the interposer substrate 700 may be referred to as a panel interposer.

A lower protective layer 703 may be disposed on the lower surface of the substrate 701, and a lower pad 705 may be disposed on the lower protective layer 703. The lower pad 705 may be connected to a through-hole electrode 730. The chip structure 1000 and the processor chip 800 may be electrically connected to the package substrate 600 through bumps 720 disposed on the lower pad 705.

The interconnection layer 710 may be disposed on the upper surface of the substrate 701 and may include an interlayer insulating layer 711 and a single-layer or multilayer interconnection structure 712. When the interconnection layer 710 has a multilayer interconnection structure, the wirings of different layers may be connected to each other through vertical contacts.

The through-hole electrode 730 may extend from the upper surface of the substrate 701 to the lower surface and penetrate the substrate 701. In addition, the through-electrode 730 may extend into the interior of the interconnection layer 710 and be electrically connected to the wirings of the interconnection layer 710. When the substrate 701 is silicon, the through-electrode 730 may be referred to as a TSV. The structure and material of the through-electrode 730 are as described in the semiconductor package 1000A of FIG. 2. According to some example embodiments, the interposer substrate 700 may include only an interconnection layer therein and may not include a through-electrode.

The interposer substrate 700 may be used for the purpose of converting and/or transmitting an input electrical signal between the package substrate 600 and the chip structure 1000 and/or the processor chip 800. Accordingly, the interposer substrate 700 may not include components such as active components or passive components. Moreover, depending on some example embodiments, the interconnection layer 710 may be disposed below the through-hole electrode 730. For example, the positional relationship between the interconnection layer 710 and the through-hole electrode 730 may be relative.

The bump 720 may be disposed on the lower surface of the interposer substrate 700 and may be electrically connected to the wiring of the interconnection layer 710. The interposer substrate 700 may be stacked on the package substrate 600 through the bump 720. The bump 720 may be connected to the wiring of the interconnection layer 710 and the lower pad 705 through the through-hole electrode 730. In some example embodiments, some of the lower pads 705 used for power or ground may be integrated and connected together to the bumps 720, so that the number of lower pads 705 may be greater than the number of bumps 720.

The logic chip or processor chip 800 may include, for example, a central processor (CPU), a graphics processor (GPU), a field programmable gate array (FPGA), a digital signal processor (DSP), an encryption processor, a microprocessor, a microcontroller, an analog-to-digital converter, an application-specific IC (ASIC), and the like. Depending on the type of elements included in the logic chip 800, the semiconductor package 10000 may be referred to as a server-oriented semiconductor package or a mobile-oriented semiconductor package.

The chip structure 1000 may have similar features to the semiconductor packages 1000, 1000A, 1000B and 1000C described with reference to FIGS. 1 to 4. For example, the chip structure 1000 may have a plurality of semiconductor chips 100 disposed on a base chip 400, and some of the plurality of semiconductor chips 100 may form a lower chip stack CS1 and others may form an upper chip stack CS2. In such a case, the thickness of each of the lower semiconductor chips disposed in the lower chip stack CS1 may be relatively greater than the thickness of each of the upper semiconductor chips disposed in the upper chip stack CS2.

The semiconductor package 10000 of some example embodiments may further include an internal (for example, inner) encapsulant covering the side and upper surface of the chip structure 1000 and the processor chip 800 on the interposer substrate 700. In addition, the semiconductor package 10000 may further include an outer encapsulant covering the interposer substrate 700 and the inner encapsulant on the package substrate 600. According to some example embodiments, the outer encapsulant and the inner encapsulant may be formed together and not be distinguished. In addition, according to some example embodiments, the inner encapsulant may cover only the upper surface of the processor chip 800 and not the upper surface of the chip structure 1000.

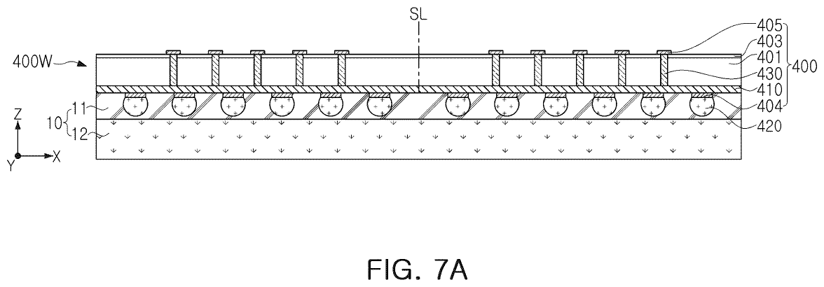

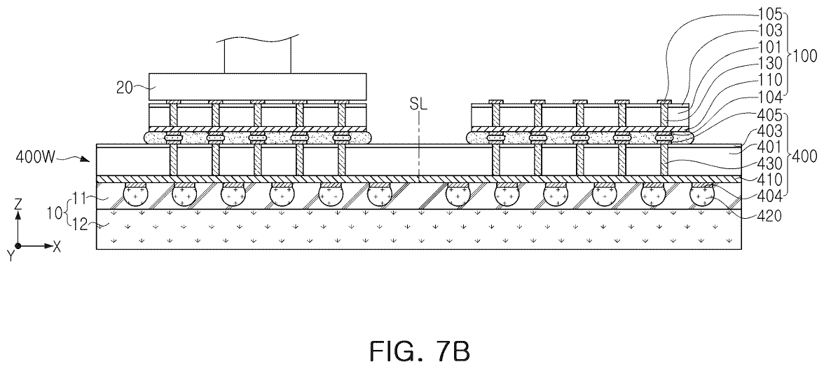

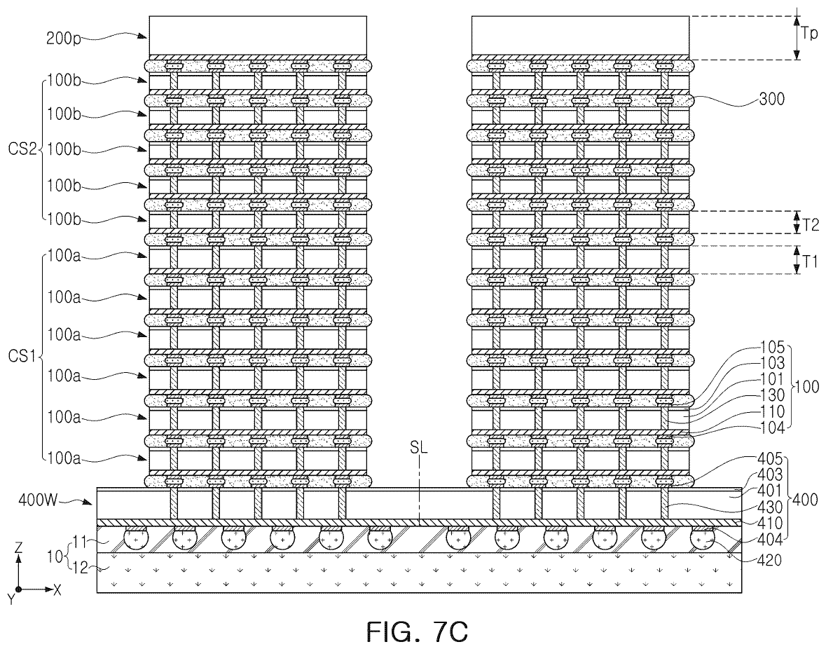

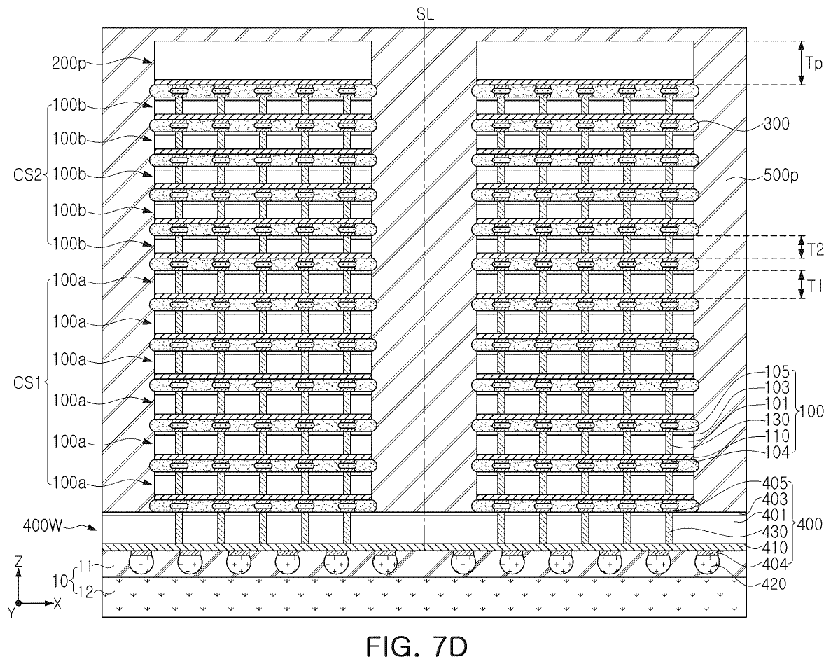

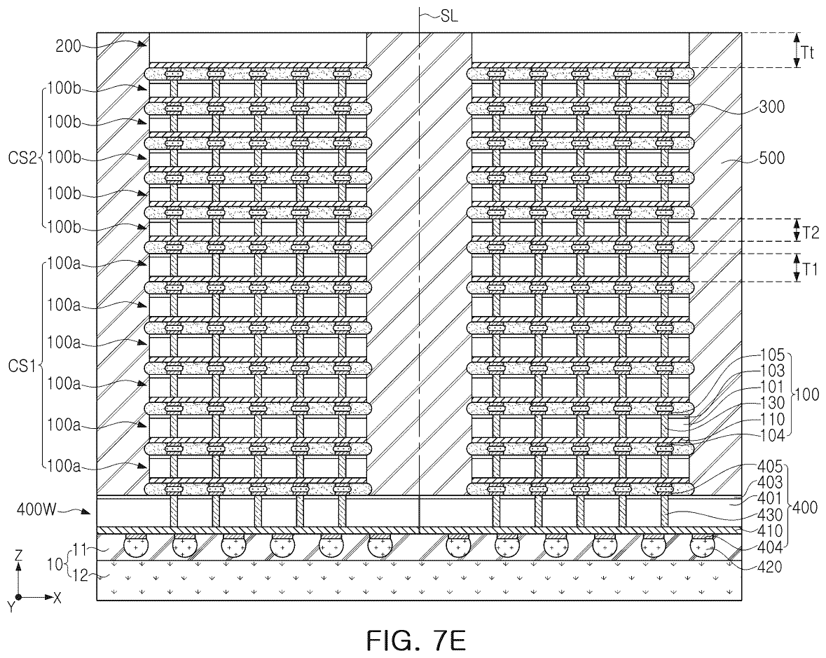

FIGS. 7A to 7E are cross-sectional views illustrating a manufacturing process of a semiconductor package according to some example embodiments according to the process sequence.

Referring to FIG. 7A, a base chip 400 disposed on a carrier 10 may be prepared. The base chip 400 may be a semiconductor wafer 400W including a plurality of base chips 400 separated by scribe lanes (SL). The semiconductor wafer 400W may be disposed on the carrier 10. The carrier 10 may be composed of a support substrate 11 and an adhesive layer 12. A semiconductor wafer 400W may be attached to the carrier 10 such that the lower surface of the base chip 400 on which the external connection terminal 420 is disposed faces the adhesive layer 12. The external connection terminal 420 may be wrapped by the adhesive layer 12, and the lower surface of the semiconductor wafer 400W may be in contact with the upper surface of the adhesive layer 12. On the upper surface of the semiconductor wafer 400W, an upper protective layer 403 of the base chip 400 and upper pads 405 disposed on the upper protective layer 403 may be disposed.

Referring to FIG. 7B, a first semiconductor chip 100a may be mounted on a base chip 400 by performing, for example, a thermocompression process. An adhesive layer 300 may be disposed below the first semiconductor chip 100a. The first semiconductor chip 100a may be, for example, vacuum-absorbed by a bonding head 20 and picked and placed onto a semiconductor wafer 100W. During the thermocompression process of the first semiconductor chip 200A, a portion of the adhesive layer 300 may have an extended region protruding from the side surface of the first semiconductor chip 100.

Referring to FIG. 7C, a plurality of first semiconductor chips 100a, a plurality of second semiconductor chips 100b, and a preliminary cover chip 200p may be sequentially stacked on the first semiconductor chip 100a by repeatedly performing the thermocompression process. The respective arrangement relationship of the plurality of first semiconductor chips 100a and the plurality of second semiconductor chips 100b is not limited to that illustrated, and it may be understood that the arrangement relationships in the embodiments (1000A, 1000B and 1000C) may be applied. The preliminary cover chip 200p may have a thickness (Tp) that is thicker than the thickness (Tt) of the cover chip 200 of FIG. 1, but is not limited thereto.

Referring to FIG. 7D, a preliminary encapsulant 500p may be formed on a semiconductor wafer 400W. The preliminary encapsulant 500p may be formed by, for example, filling an encapsulant on a semiconductor wafer 400W to cover the plurality of semiconductor chips 100 and the preliminary cover chip 200p, and then curing the encapsulant. The preliminary encapsulant 500p may surround or at least partially surround respective side surfaces of the plurality of semiconductor chips 100, the adhesive layers 300 and the preliminary cover chip 200p, on the base chip 400, and may cover the upper surface of the preliminary cover chip 200p. The upper surface of the preliminary encapsulant 500p may be located at a higher level than the upper surface of the preliminary cover chip 200p.

Referring to FIG. 7E, the upper surfaces of the preliminary encapsulant 500p and the preliminary cover chip 200p may be polished to form the encapsulant 500 and the cover chip 200. The upper surfaces of the encapsulant 500 and the cover chip 200 may be flattened using a polishing device. By the flattening process, the upper surface of the encapsulant 500 may be located coplanar or substantially coplanar with the upper surface of the cover chip 200. The planarization process may be performed, for example, by a CMP (Chemical Mechanical Polishing) process. The thickness (Tt) of the cover chip 200 may be smaller than the thickness (Tp) of the preliminary cover chip 200p, and may have a value greater than a value of respective thicknesses T1 and T2 of the plurality of first semiconductor chips 100a and the plurality of second semiconductor chips 100b as described above.

In a subsequent process, the encapsulant 500 and the semiconductor wafer 400W may be cut along the scribe lane (SL) to separate the plurality of semiconductor packages 1000. The plurality of semiconductor packages 1000 may include features identical to or similar to the semiconductor packages described with reference to FIGS. 1 to 4. The semiconductor package 1000 completed through the manufacturing process may provide semiconductor packages 1000 with improved reliability by controlling warpage accumulated as chips are stacked by placing relatively thick semiconductor chips in a lower region.

As set forth above, according to example embodiments, in a multilayer semiconductor chip structure, a semiconductor package having improved reliability may be provided by disposing a relatively thick semiconductor chip in a lower region.

While example embodiments have been illustrated and described above, it will be apparent to those ordinarily skilled in the art that modifications and variations could be made without departing from the spirit and scope of the present inventive concepts as in the appended claims.

Terms, such as first, second, etc. may be used herein to describe various elements, but these elements should not be limited by these terms. The above terms are used only for the purpose of distinguishing one component from another. For example, a first element may be termed a second element, and, similarly, a second element may be termed a first element, without departing from the scope of the present disclosure.

What is claimed is:

1. A semiconductor package, comprising:
a base chip;
a plurality of semiconductor chips stacked on the base chip in a direction perpendicular to an upper surface of the base chip and including through-silicon vias;
a cover chip on the plurality of semiconductor chips;
bump structures below the cover chip and each of the plurality of semiconductor chips and electrically connected to the through-silicon vias;
adhesive layers below the cover chip and each of the plurality of semiconductor chips, the adhesive layers at least partially surrounding each of the bump structures, ; and
an encapsulant on the base chip and at least partially surrounding the plurality of semiconductor chips and the cover chip,
wherein the plurality of semiconductor chips includes at least one first semiconductor chip adjacent to the base chip, and at least one second semiconductor chip adjacent to the cover chip,
the at least one second semiconductor chip has a second thickness that is smaller than a first thickness of the at least one first semiconductor chip, and
a width of each of the plurality of semiconductor chips in a horizontal direction is smaller than a width of the base chip in the horizontal direction.

2. The semiconductor package of claim 1, wherein the at least one first semiconductor chip includes six first semiconductor chips, and
the at least one second semiconductor chip includes five second semiconductor chips.

3. The semiconductor package of claim 2, wherein a sum of individual thicknesses of the plurality of first semiconductor chips has a value that is greater than a sum of individual thicknesses of the plurality of second semiconductor chips.

4. The semiconductor package of claim 1, further comprising:
at least one third semiconductor chip between the at least one first semiconductor chip and the at least one second semiconductor chip,
wherein the at least one third semiconductor chip has a third thickness that is smaller than the first thickness and greater than the second thickness.

5. The semiconductor package of claim 1, wherein each of the plurality of semiconductor chips has a different thickness, and
a thickness of each of the plurality of semiconductor chips decreases from the base chip toward the cover chip.

6. The semiconductor package of claim 1, further comprising at least one third semiconductor chip between the at least one first semiconductor chip and the at least one second semiconductor chip,
wherein the at least one third semiconductor chip has a third thickness that is greater than the first thickness and the second thickness.

7. The semiconductor package of claim 1, wherein the base chip includes a through-electrode that is electrically connected to the bump structures, and
the base chip is electrically connected to the cover chip and to the plurality of semiconductor chips through the through-electrode.

8. The semiconductor package of claim 1, wherein the cover chip does not include a through-silicon via.

9. The semiconductor package of claim 1, wherein the cover chip has a thickness that is greater than the first thickness and the second thickness.

10. The semiconductor package of claim 1, wherein the base chip is a logic chip, and
each of the plurality of semiconductor chips is a memory chip.

11. The semiconductor package of claim 1, wherein the first thickness is in a range of 43 μm to 60 μm, and
the second thickness is in a range of 40 μm to 48 μm.

12. The semiconductor package of claim 1, wherein a maximum width of each of the adhesive layers in a horizontal direction is greater than the width of each of the plurality of semiconductor chips in the horizontal direction.

13. The semiconductor package of claim 1, further comprising:
external connection terminals below the base chip and electrically connected to the base chip.

14. A semiconductor package, comprising:
a base chip;
a plurality of semiconductor chips stacked on the base chip in a direction perpendicular to an upper surface of the base chip and including through-silicon vias;
bump structures below each of the plurality of respective semiconductor chips and electrically connected to the through-silicon vias;
adhesive layers below each of the plurality of semiconductor chips and at least partially surrounding each of the bump structures and; and
an encapsulant on the base chip and at least partially surrounding side surfaces of each of the semiconductor chips,
wherein the plurality of semiconductor chips includes lower semiconductor chips on the base chip and defining a lower chip stack, and upper semiconductor chips on the lower chip stack and defining an upper chip stack,
a number of the lower semiconductor chips in the lower chip stack is greater than or equal to a number of the upper semiconductor chips in the upper chip stack, and
a sum of individual thicknesses of the lower semiconductor chips is greater than a sum of individual thicknesses of the upper semiconductor chips.

15. The semiconductor package of claim 14, wherein the lower semiconductor chips include first lower semiconductor chips and second lower semiconductor chips stacked on the base chip,
wherein the first lower semiconductor chips and the second lower semiconductor chips have different thicknesses.

16. The semiconductor package of claim 15, wherein each of the second lower semiconductor chips has a thickness that is greater than a thickness of each of the first lower semiconductor chips.

17. The semiconductor package of claim 14, wherein each of side surfaces of the lower chip stack and the upper chip stack are aligned.

18. The semiconductor package of claim 14, wherein individual thicknesses of the lower semiconductor chips are thinner towards a top of the semiconductor package, and
individual thicknesses of the upper semiconductor chips are thinner towards the top of the semiconductor package.

19. A semiconductor package, comprising:
a base chip;
a plurality of semiconductor chips stacked on the base chip in a direction perpendicular to an upper surface of the base chip and including a through-silicon via electrically connected to the base chip; and
an encapsulant on the base chip and covering at least a portion of each of the plurality of semiconductor chips and of the base chip,
wherein the plurality of semiconductor chips includes a first semiconductor chip and a second semiconductor chip on the first semiconductor chip,
a gap between the base chip and the first semiconductor chip is smaller than a gap between the base chip and the second semiconductor chip, and
the first semiconductor chip has a first thickness that is greater than a second thickness of the second semiconductor chip.

20. The semiconductor package of claim 19, wherein the plurality of semiconductor chips includes at least one first semiconductor chip and at least one second semiconductor chip on the at least one first semiconductor chip, and
a number of the at least one first semiconductor chip is greater than or equal to a number of the at least one second semiconductor chip.
